(19) United States
(12) Patent Application Publication
(10) Pub. No.: US 2026/0314188 A1
(43) Pub. Date: Oct. 8, 2026

(54) ELECTRONIC COMPONENTS AND ELECTRONIC DEVICE INCLUDING THE SAME

(71) Applicant: SAMSUNG DISPLAY CO., LTD., YONGIN-SI (KR)

(72) Inventors: KIYONG KIM, Yongin-si (KR); HEEJU WOO, Yongin-si (KR); CHOLONG WON, Yongin-si (KR); HYUNGBIN CHO, Yongin-si (KR)

(21) Appl. No.: 19/459,072

(22) Filed: Jan. 26, 2026

(30) Foreign Application Priority Data
Mar. 25, 2025 (KR) 10-2025-0037687

(51) Int. Cl. H10K 59/123; H10K 59/131

(52) U.S. Cl. CPC H10K 59/123; H10K 59/131

(57) ABSTRACT

An electronic device includes a display panel including a first pad, an electronic component electrically connected to the display panel, an adhesive layer bonding the display panel and the electronic component, and a conductive particle disposed in the adhesive layer to electrically connect the display panel and the electronic component. The electronic component includes a second pad, an insulating layer in which a plurality of openings is defined to expose a portion of the second pad, and a contact electrode disposed on the insulating layer and connected to the second pad through the plurality of openings.

### CROSS-REFERENCE TO RELATED APPLICATIONS

This application claims priority under 35 U.S.C. § 119 of Korean Patent Application No. 10-2025-0037687, filed on March 25, 2025, the disclosure of which is hereby incorporated by reference in its entirety.

### TECHNICAL FIELD

Embodiments of the inventive concept relate to an electronic component and an electronic device including the same, and more specifically, to an electronic component, and a pad area of an electronic device.

### DISCUSSION OF RELATED ART

Various display devices used in multimedia equipment such as televisions, mobile phones, table computers, navigation devices, and game consoles are being developed. Electronic devices may display images and detect external inputs.

An electronic device may include a display area that is activated according to electrical signals. Through the display area, the electronic device may detect externally applied inputs and simultaneously display various images to provide information to a user.

The electronic device may include a display panel in which pixels are arranged. The electronic device may include a pad part for input and output of signals to control an operation of the display panel, and the pad part may include a driving chip or a circuit board. The display panel may be bonded to the driving chip and/or the circuit board.

The driving chip and/or the circuit board may include bumps, and the driving chip and/or the circuit board may be bonded to the display panel through the bumps.

### SUMMARY

Embodiments of the inventive concept provide an electronic component in which bonding reliability is improved, and an electronic device including the electronic component.

An embodiment of the inventive concept provides an electronic device including a display panel including a first pad, an electronic component electrically connected to the display panel, an adhesive layer bonding the display panel and the electronic component to each other, and a conductive particle disposed in the adhesive layer and configured to electrically connect the display panel and the electronic component to each other. The electronic component includes a second pad, an insulating layer in which a plurality of openings exposing a portion of the second pad are defined, and a contact electrode disposed on the insulating layer and connected to the second pad through the plurality of openings.

In an embodiment, in a plan view, the second pad may extend in a first direction, and each of the plurality of openings extends along the first direction.

In an embodiment, a length of each of the plurality of openings in a second direction intersecting the first direction may be smaller than a diameter of the conductive particle.

In an embodiment, the plurality of openings may be spaced apart from each other in a second direction intersecting the first direction.

In an embodiment, a length of each of the plurality of openings in the first direction may be greater than a length in a second direction intersecting the first direction.

In an embodiment, the contact electrode may include a first metal layer directly disposed on the second pad, and a second metal layer disposed on the first metal layer. The first metal layer may include titanium–tungsten (TiW) alloy, and the second metal layer may include gold (Au).

In an embodiment, the electronic component may be a driving chip.

In an embodiment, the electronic component does not include a bump protruding from the contact electrode.

In an embodiment, in a plan view, the second pad may extend in a first direction, each of the plurality of openings may extend in a second direction intersecting the first direction, the plurality of openings may be spaced apart from each other in the first direction, and a length of each of the plurality of openings in the first direction may be smaller than a diameter of the conductive particle.

In an embodiment, in a plan view, the second pad may extend in a first direction, each of the plurality of openings may extend in a second direction intersecting the first direction and extend in a first diagonal direction between the first direction and the second direction, the plurality of openings may be spaced apart from each other in a second diagonal direction intersecting the first diagonal direction, and a length of each of the plurality of openings in the second diagonal direction may be smaller than a diameter of the conductive particle.

In an embodiment, the plurality of openings may be arranged in a matrix shape defining a plurality of rows and a plurality of columns.

In an embodiment, in a plan view, the second pad may extend in a first direction, each of the plurality of openings may have a circular shape, and the plurality of openings may be spaced apart from each other in the first direction and a second direction intersecting the first direction.

In an embodiment of the inventive concept, an electronic device includes a display panel including a first pad, an electronic component electrically connected to the display panel, and an adhesive layer configured to bond the display panel and the electronic component to each other. The electronic component includes a second pad, an insulating layer in which a plurality of openings exposing a portion of the second pad are defined, and a contact electrode disposed on the insulating layer and connected to the second pad through the plurality of openings.

In an embodiment, the first pad may include a first conductive pattern, a polymer pattern disposed on the first conductive pattern, and a second conductive pattern disposed on the first conductive pattern and covering the polymer pattern.

In an embodiment, in a plan view, the second pad may extend in a first direction, each of the plurality of openings may extend along the first direction, the plurality of openings may be spaced apart in a second direction intersecting the first direction, and a length of each of the plurality of openings in the second direction may be smaller than a length of the polymer pattern in the second direction.

In an embodiment, the contact electrode may include a first metal layer directly disposed on the second pad and a second metal layer disposed on the first metal layer. The first metal layer may include titanium–tungsten (TiW) alloy, and the second metal layer may include gold (Au).

In an embodiment, the electronic component may be a driving chip.

In an embodiment, the electronic component does not include a bump protruding from the contact electrode.

In an embodiment of the inventive concept, an electronic component includes a driving integrated circuit, a driving pad, an insulating layer in which a plurality of openings exposing a portion of the driving pad are defined, and a contact electrode disposed on the insulating layer and connected to the driving pad through the plurality of openings.

In an embodiment, in a plan view, the driving pad may extend in a first direction, each of the plurality of openings may extend along the first direction, and the plurality of openings may be spaced apart in a second direction intersecting the first direction.

### BRIEF DESCRIPTION OF THE DRAWINGS

The above and other features of the present disclosure will become more apparent by describing in detail embodiments thereof with reference to the accompanying drawings, in which:

FIG. 1 is a block diagram of an electronic device according to an embodiment of the inventive concept;

FIG. 2 is a schematic view of electronic devices according to various embodiments of the inventive concept;

FIG. 3 is a perspective view of an electronic device according to an embodiment of the inventive concept;

FIG. 4 is an exploded perspective view of the electronic device according to an embodiment of the inventive concept;

FIG. 5 is a cross-sectional view of a display device according to an embodiment of the inventive concept;

FIG. 6 is an enlarged cross-sectional view of the display panel according to an embodiment of the inventive concept;

FIG. 7 is a plan view of a display panel according to an embodiment of the inventive concept;

FIG. 8 is a cross-sectional view of the display panel according to an embodiment of the inventive concept;

FIG. 9 is an enlarged exploded perspective view of a pad area of the electronic device according to an embodiment of the inventive concept;

FIG. 10A is a plan view illustrating the pad area of the display panel according to an embodiment of the inventive concept;

FIG. 10B is a plan view illustrating a pad area of a driving chip according to an embodiment of the inventive concept;

FIGS. 10C and 10D are cross-sectional views illustrating the pad area of the electronic device according to an embodiment of the inventive concept, respectively;

FIG. 11A is a plan view illustrating a pad area of a display panel according to an embodiment of the inventive concept;

FIG. 11B is a cross-sectional view illustrating a pad area of an electronic device according to an embodiment of the inventive concept; and

FIGS. 12A to 12F are plan views illustrating pad areas of driving chips according to an embodiments of the inventive concept, respectively.

### DETAILED DESCRIPTION

Embodiments of the present disclosure will be described more fully hereinafter with reference to the accompanying drawings. Like reference numerals may refer to like elements throughout the accompanying drawings.

It should be understood that descriptions of features or aspects within each embodiment should typically be considered as available for other similar features or aspects in other embodiments, unless the context clearly indicates otherwise.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

As used herein, the term "and/or" includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

The terminology used herein is for the purpose of describing particular embodiments only and is not intended to be limiting of the invention. As used herein, the singular forms, "a", "an" and "the" are intended to include the plural forms as well, unless the context clearly indicates otherwise.

Spatially relative terms, such as "beneath", "below", "lower", "above", "upper" and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as "below" or "beneath" other elements or features would then be oriented "above" the other elements or features. Thus, the exemplary term "below" can encompass both an orientation of above and below. The device may be otherwise oriented (rotated 90 degrees or at other orientations) and the spatially relative descriptors used herein interpreted accordingly. Other words used to describe the relationships between components should be interpreted in a like fashion.

It will be further understood that the terms "includes" and/or "including", when used in this specification, specify the presence of stated features, integers, steps, operations, elements, and/or components, but do not preclude the presence or addition of one or more other features, integers, steps, operations, elements, components, and/or groups thereof.

Embodiments of the inventive concept relate to a display device and a method of manufacturing the same, and more particularly, to a display panel and driving chip structure that can maintain stable electrical and mechanical bonding even in the presence of alignment variation. In embodiment, the display panel and the driving chip are connected through a pad area structure including conductive patterns, contact electrodes, and openings formed in insulating layers. The arrangement, shape, and dimensions of these openings, as well as the configuration of conductive patterns and polymer patterns in the pad area, are selected to improve contact uniformity, reduce bonding distance variation, and enhance overall connection reliability.

In embodiments, a polymer pattern may be disposed between conductive patterns of the display panel to define a protrusion in a thickness direction and provide localized support for bonding with the driving chip. Openings formed in the insulating layer of the driving chip can be shaped and arranged to increase the effective contact area between the contact electrodes and conductive patterns of the display panel, thereby mitigating the effects of positional misalignment. The structural cooperation of these features can reduce the occurrence of bonding defects such as non-contact regions or excessive bonding gaps, improving yield and operational reliability.

By applying these design features, the display device according to embodiments can achieve stable electrical connections and mechanical adhesion without needing overly strict alignment tolerances during assembly. The disclosed pad area structures can also be adapted to accommodate different display panel configurations and manufacturing processes, enabling improved performance in a range of display applications, including those having narrow bezels or high-resolution pixel arrangements. This arrangement may facilitate reduced electrical resistance, improved durability against environmental and mechanical stresses, and enhanced overall display quality.

A display device according to an embodiment of the inventive concept may be applied to various electronic devices. An electronic device according to an embodiment may include the above-described display device, and may further include a module or a device having additional functions besides the display device.

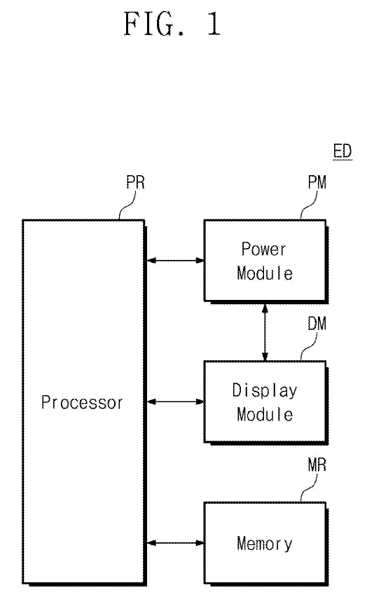

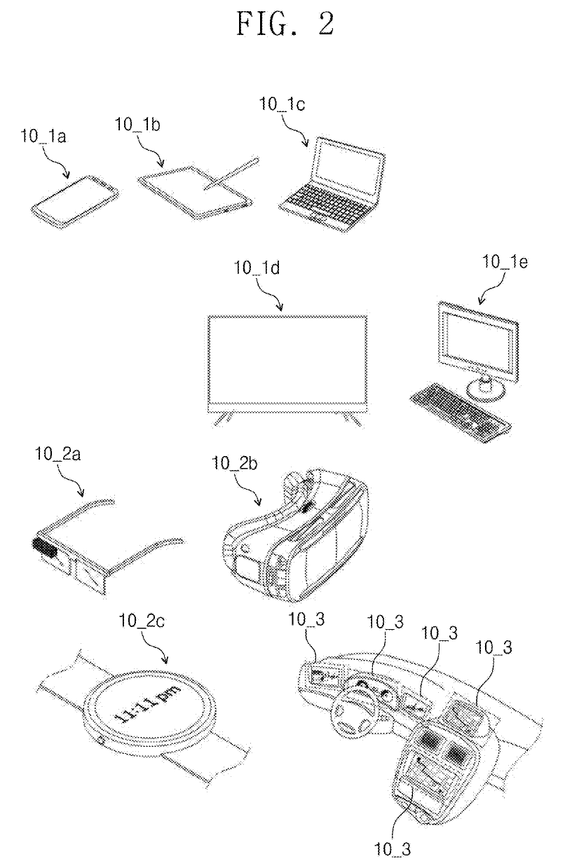

FIG. 1 is a block diagram of an electronic device ED according to an embodiment of the inventive concept. FIG. 2 is a schematic view of electronic devices ED according to various embodiments of the inventive concept.

Referring to FIG. 1, the electronic device ED according to an embodiment may include a display module DM (also referred to as a display device), a processor PR, a memory MR, and a power module PM (also referred to as a power device).

The processor PR may include at least one of, for example, a central processing unit (CPU), an application processor (AP), a graphic processing unit (GPU), a communication processor (CP), an image signal processor (ISP), and a controller.

The memory MR may store data or information utilized for an operation of the processor PR or the display module DM. When the processor PR executes an application stored in the memory MR, an image data signal and/or an input control signal may be transmitted to the display module DM, and the display module DM may process the transmitted signal and output image information through a display screen.

The power module PM may include a power supply module, such as a power adapter or a battery device, and a power conversion module that converts power supplied by the power supply module to generate power utilized for the operation of the electronic device ED.

At least one of the above-described components of the electronic device ED may be included in the display device according to the above-described embodiments. In addition, some of the individual modules included in one functional module may be included in the display device, and the others may be provided separately from the display device. For example, the display device may include the display module DM, and the processor PR, the memory MR, and the power module PM may be provided as other type of devices within the electronic device ED, rather than in the display device.

Referring to FIG. 2, the various electronic devices ED to which the display device according to the embodiments is applied may include not only image display electronic devices such as, for example, a smartphone 10_1a, a tablet computer 10_1b, a laptop 10_1c, a TV 10_1d, and a computer monitor 10_1e, but also wearable electronic devices including a display module such as smart glasses 10_2a, a head-mounted display 10_2b, and a smartwatch 10_2c, and vehicle electronic devices including a display module such as an instrument panel, a center fascia, a dashboard-mounted center information display (CID), and a room mirror display 10_3.

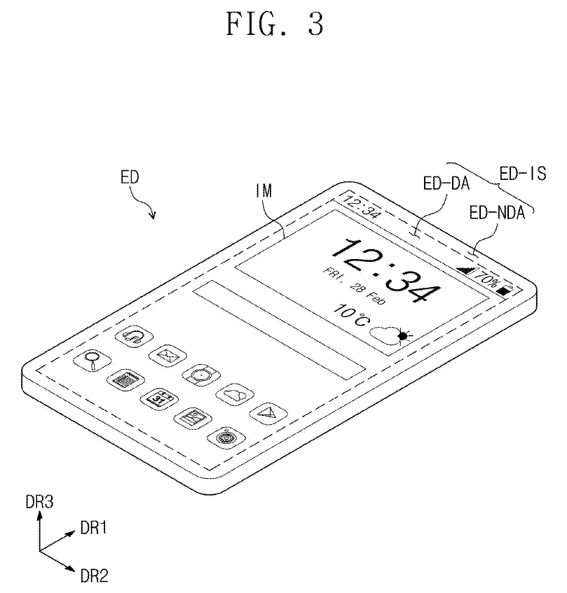

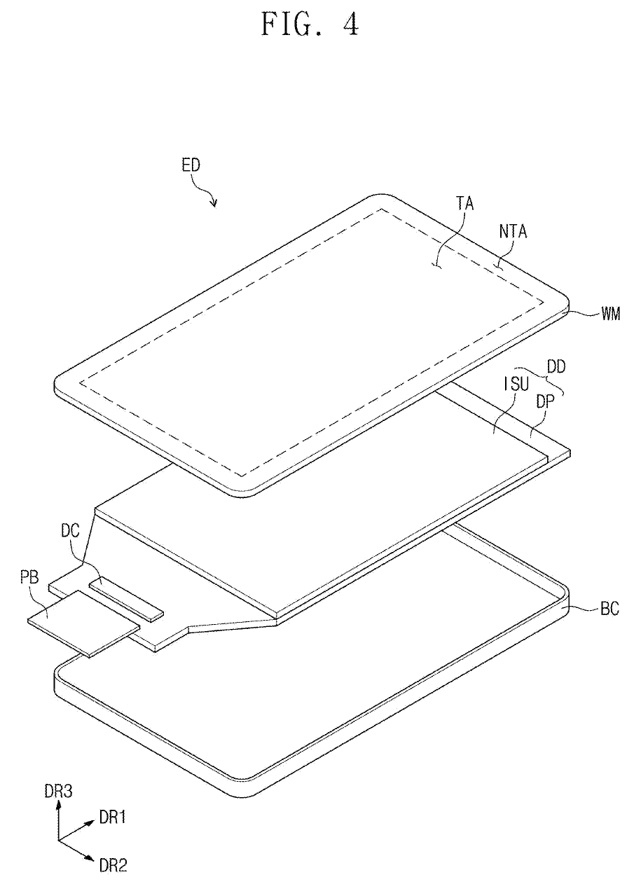

FIG. 3 is a perspective view of an electronic device ED according to an embodiment of the inventive concept. FIG. 4 is an exploded perspective view of the electronic device ED according to an embodiment of the inventive concept.

In FIGS. 3 and 4, a smartphone is illustrated as one example of the electronic device ED. Referring to FIG. 3, the electronic device ED may display an image IM through a display surface ED-IS. As one example of the image IM, icon images are illustrated. The display surface ED-IS is parallel to a surface defined by a first direction DR1 and a second direction DR2. A normal direction of the display surface ED-IS, that is, a thickness direction of the electronic device ED, is defined as a third direction DR3. In the present specification, the expression "in a planar view" or "when viewed in a planar view" may refer to a case viewed from the third direction DR3. The terms “planar view” and “plan view” may be used interchangeably herein and may refer to a case viewed from above (e.g., from the third direction DR3). A front surface (or a top surface) and a rear surface (or a bottom surface) of each of layers or units, which will be described below, are distinguished by the third direction DR3.

In addition, the display surface ED-IS may include a display area ED-DA in which the image IM is displayed, and a non-display area ED-NDA adjacent to the display area ED-DA. The non-display area ED-NDA is an area in which the image is not displayed. However, it is not limited thereto, and the non-display area ED-NDA may be adjacent to one side of the display area ED-DA or may be omitted.

Referring to FIG. 4, the electronic device ED may include a window WM, a display device DD, and a housing BC. The housing BC may accommodate the display device DD and be coupled to the window WM. In an embodiment, the electronic device ED may further include other electronic modules accommodated in the housing BC and electrically connected to a display panel DP.

The window WM is disposed on the display device DD and may transmit the image provided from the display device DD to outside of the electronic device ED. The window WM may include a transmission area TA and a non-transmission area NTA. The transmission area TA may overlap the display area ED-DA of FIG. 3 and may have a shape corresponding to the display area ED-DA.

The non-transmissive area NTA may overlap the non-display area ED-NDA (see FIG. 3) and may have a shape corresponding to the non-display area ED-NDA (see FIG. 3). The non-transmission area NTA may be an area having a light transmittance that is relatively less than that of the transmission area TA.

The display device DD may generate images and detect external inputs. The display device DD may include the display panel DP and an input sensor ISU. In an embodiment, the display device DD may further include an anti-reflection member disposed on the input sensor ISU. The anti-reflection material may include a polarizer and a retarder or may include a color filter and a black matrix.

According to an embodiment of the inventive concept, the display panel DP may be a light-emitting display panel, and its type is not particularly limited. For example, the display panel DP may be an organic light-emitting display panel or an inorganic light-emitting display panel. An emission layer of the organic light-emitting display panel may include an organic light emitting material. The emission layer of the inorganic light-emitting display panel may include, for example, quantum dots, quantum rods, nano LEDs, etc. Hereinafter, the display panel DP will be described as an organic light-emitting display panel.

The input sensor ISU may include any one of a capacitive sensor, an optical sensor, an ultrasonic sensor, and an electromagnetic induction sensor. The input sensor ISU may be provided on the display panel DP through a continuous process or may be manufactured separately and then attached to an upper side of the display panel DP through an adhesion layer.

The display device DD of an embodiment may further include a driving chip DC (e.g., a driving integrated circuit (IC)) and a circuit board PB. An embodiment in which the driving chip DC is mounted on the display panel DP is illustrated, but it is not limited thereto. For example, the driving chip DC may be mounted on the circuit board PB. In an embodiment, the driving chip DC and the circuit board PB, which are electrically connected to the display panel DP, may form and be collectively referred to as an electronic component. In an embodiment, a driving integrated circuit, a driving pad, an insulating layer, and a contact electrode, which are described in further detail below, may form and be collectively referred to as an electronic component.

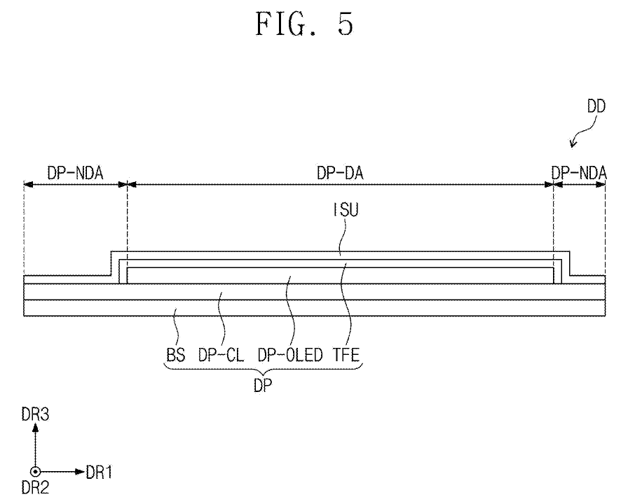

The driving chip DC may generate a driving signal utilized for the operation of the display panel DP based on a control signal transmitted from the circuit board PB. The circuit board PB bonded to the display panel DP may be bent and disposed on a rear surface of the display panel DP. The circuit board PB may be disposed on one end of a base layer BS (see FIG. 5) and may be electrically connected to a circuit element layer DP-CL (see FIG. 5).

In the display device DD of an embodiment, a portion of the display panel DP may be bent so that the driving chip DC faces downward. A portion of the non-display area ED-NDA (see FIG. 3) of the display panel DP may be bent. However, the bent portion is not limited thereto, and the circuit board PB may be bent.

Although a smartphone is described above as the electronic device ED, in the present specification, the electronic device ED is sufficiently constituted when it includes two or more bonded electronic components. Each of the display panel DP and the driving chip DC mounted on the display panel DP corresponds to a different electronic component, and these components alone may constitute the electronic device ED. The display panel DP and the circuit board PB connected to the display panel DP may by themselves constitute the electronic device ED, and a main board and an electronic module mounted on the main board may also by themselves constitute the electronic device ED. Hereinafter, the display device DD and the electronic device ED according to embodiments of the inventive concept will be described, focusing on a bonding structure of the display panel DP and the driving chip DC mounted on the display panel DP.

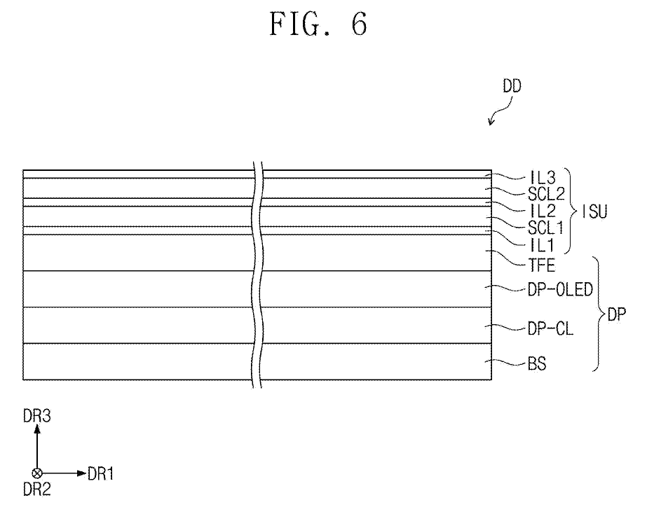

FIG. 5 is a cross-sectional view of a display device DD according to an embodiment of the inventive concept. FIG. 6 is an enlarged cross-sectional view of the display device DD.

Referring to FIG. 5, the display device DD may include the display panel DP and the input sensor ISU. The display panel DP may include a base layer BS, a circuit element layer DP-CL disposed on the base layer BS, a display element layer DP-OLED, and a thin-film encapsulation layer TFE. The input sensor ISU may be disposed on the thin-film encapsulation layer TFE.

The display panel DP may include a display area DP-DA and a non-display area DP-NDA. The display area DP-DA of the display panel DP corresponds to the display area ED-DA shown in FIG. 3 or the transmission area TA shown in FIG. 4, and the non-display area DP-NDA corresponds to the non-display area ED-NDA shown in FIG. 3 or the non-transmission area NTA shown in FIG. 4.

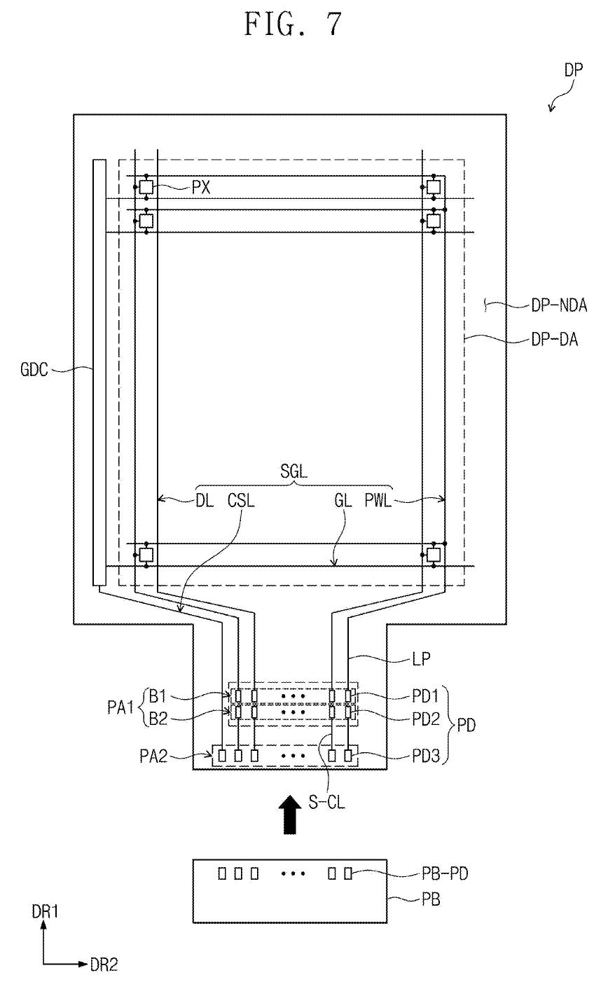

In embodiments, at least a portion of the non-display area DP-NDA may include the first pad area PA1 (see FIG. 7) configured for connection to the electronic component, such as the driving chip DC. As described in more detail below, the first pad area PA1 may incorporate the pad and insulating layer configuration having a plurality of openings to facilitate bumpless bonding to the driving chip DC via conductive particles or a polymer pattern.

The base layer BS may include the display area DP-DA and the non-display area DP-NDA surrounding the display area DP-DA. The base layer BS may include a synthetic resin film. The base layer BS may have a multilayer structure. For example, the base layer BS may have a three-layer structure of a synthetic resin layer, an inorganic layer, and a synthetic resin layer. For example, the synthetic resin layer may be a polyimide resin layer, and the material thereof is not particularly limited. The synthetic resin layer may include at least one of, for example, an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. In addition, the base layer BS may include a glass substrate, a metal substrate, or an organic/inorganic composite substrate.

The circuit element layer DP-CL may include at least one insulating layer and circuit element. The insulating layer may include at least one inorganic layer and at least one organic layer. The circuit element may include, for example, signal lines, a pixel driving circuit, and the like. The insulating layer, a semiconductor layer, and a conductive layer may be provided through processes such as coating or deposition. Subsequently, the insulating layer, the semiconductor layer, and the conductive layer may be selectively patterned through photolithography and etching processes. Through such processes, a semiconductor pattern, a conductive pattern, and a signal line may be provided. Patterns disposed on the same layer may be provided through the same process. In the present specification, “the patterns are provided through the same process” means that the patterns include the same material and have the same laminated structure.

The display element layer DP-OLED may include an organic light-emitting element. The display element layer DP-OLED may further include an organic layer such as a pixel defining layer.

The thin film encapsulation layer TFE may be disposed on the circuit element layer DP-CL to cover the display element layer DP-OLED. The thin-film encapsulation layer TFE may overlap the display area DP-DA and the non-display area DP-NDA. The thin-film encapsulation layer TFE may overlap at least a portion of the non-display area DP-NDA. The thin film encapsulation layer TFE may protect the pixels from, for example, moisture, oxygen, and external foreign substances. However, it is not limited thereto, and the thin-film encapsulation layer TFE may further include an additional insulating layer other than the thin-film encapsulation layer. For example, it may further include an optical insulating layer for controlling refractive index.

In an embodiment of the inventive concept, an encapsulation substrate may be provided instead of the thin-film encapsulation layer TFE, and the encapsulation substrate may face the base layer BS, the circuit element layer DP-CL and the display element layer DP-OLED may be disposed between the encapsulation substrate and the base layer BS.

The input sensor ISU may be directly disposed on the display panel DP. In this specification, that “a constituent A is directly disposed on a constituent B” may mean that an adhesive member is not disposed between the constituents A and B. In an embodiment, the input sensor ISU may be manufactured by a continuous process with the display panel DP. However, the technical spirit of the inventive concept is not limited thereto, and the input sensor ISU may be provided as a separate panel and coupled to the display panel DP through an adhesive layer. According to an embodiment, the input sensor ISU may be omitted.

Referring to FIG. 6, the input sensor ISU may detect an external input and provide an input signal including information on the external input so that the display panel DP may display an image corresponding to the external input. The input sensor ISU may operate by various methods such as, for example, a capacitive method, a resistive film method, an infrared method, an acoustic method, or a pressure method, and the driving method of the input sensor ISU is not limited to any one of methods, if it may detect an external input. In an embodiment, the input sensor ISU is described as an input sensing panel operating by a capacitive method.

The input sensor ISU may include a base layer IL1, a first sensing conductive layer SCL1, a first sensing insulating layer IL2, a second sensing conductive layer SCL2, and a second sensing insulating layer IL3, which are sequentially laminated in a third direction DR3. The base layer IL1 of the input sensor ISU may be in contact (e.g., direct contact) with the thin-film encapsulation layer TFE. However, embodiments are not limited thereto, and at least one of the base layer IL1 and the second sensing insulating layer IL3 may be omitted.

In embodiments, a portion of the non-display area DP-NDA underlying the input sensor ISU may include the first pad area PA1 for coupling to the driving chip DC. The first pad area PA1 may incorporate the pad and insulating layer configuration with multiple openings to facilitate bumpless electrical connection to the driving chip DC, as described in detail below.

Each of the first sensing conductive layer SCL1 and the second sensing conductive layer SCL2 may have a single-layer or multi-layer structure. A multi-layer conductive layer may include at least two or more of transparent conductive layers and metal layers. The multi-layer conductive layer may include metal layers containing different metals. The transparent conductive layer may include at least one of, for example, indium tin oxide (ITO), indium zinc oxide (IZO), zinc oxide (ZnO), indium tin zinc oxide (ITZO), Poly(3,4-ethylenedioxythiophene) (PEDOT), a metal nanowire, or graphene. The metal layer may include at least one of, for example, molybdenum, silver, titanium, copper, aluminum, and alloys thereof. For example, each of the first sensing conductive layer SCL1 and the second sensing conductive layer SCL2 may have a two-layer structure, such as an ITO/copper two-layer structure, or, without being limited thereto, and the first and second sensing conductive layers SCL1 and SCL2 may have a three-layer structure including titanium/aluminum/titanium.

Each of the first sensing conductive layer SCL1 and the second sensing conductive layer SCL2 may include sensing conductive patterns. The sensing conductive patterns of the first sensing conductive layer SCL1 and the second sensing conductive layer SCL2 may provide sensing electrodes and sensing lines connected thereto, which constitute the input sensor ISU.

Each of the base layer IL1, the first sensing insulating layer IL2, and the second sensing insulating layer IL3 may include at least one of, for example, an inorganic film and an organic film. For example, the inorganic film may include at least one of, for example, aluminum oxide, titanium oxide, silicon oxide, silicon oxynitride, zirconium oxide, and hafnium oxide.

The organic film may include at least one of, for example, acrylic resin, methacrylic resin, polyisoprene, vinyl resin, epoxy resin, urethane resin, cellulose resin, siloxane resin, polyimide resin, polyamide resin, and parylene resin. However, the materials of the inorganic film and the organic film are not limited to the above examples. In an embodiment, the base layer IL1 may include an inorganic film, and the first sensing insulating layer IL2 and the second sensing insulating layer IL3 may include organic films, but embodiments are not limited thereto.

FIG. 7 is a plan view of the display panel DP according to an embodiment of the inventive concept. FIG. 7 illustrates a planar shape of the display panel DP shown in FIG. 6.

Referring to FIG. 7, the display panel DP may include a plurality of pixels PX, a gate driving circuit GDC, a plurality of signal lines SGL, and a plurality of signal pads PD.

The pixels PX are disposed in the display area DP-DA. Each of the pixels PX may include a light-emitting element and a pixel driving circuit connected thereto. The gate driving circuit GDC may sequentially output gate signals to a plurality of gate lines GL, which will be described further below. The transistors of the gate driving circuit GDC may be formed through the same process as the transistors of the pixel PX such as a low temperature polycrystalline silicon (LTPS) process or a low temperature polycrystalline oxide (LTPO) process. The display panel DP may further include another driving circuit that provides emission control signals to the pixels PX.

The signal lines SGL may include gate lines GL, data lines DL, power lines PWL, and control signal lines CSL. The gate lines GL may be respectively connected to corresponding pixels of the pixels PX, and the data lines DL may be respectively connected to corresponding pixels PX of the pixels PX. The power line PWL may be connected to the pixels PX. A control signal line CSL may be connected to the gate driving circuit GDC and provide control signals to the driver.

The signal lines SGL may overlap the display area DP-DA and the non-display area DP-NDA. Each of the signal lines SGL may include a line part. The line part may overlap the display area DP-DA and the non-display area DP-NDA.

The plurality of signal pads PD may include first pads PD1, second pads PD2, and third pads PD3. In the present specification, the signal pads PD may be referred to as pads. An area on which the first pads PD1 and the second pads PD2 are disposed may be defined as a first pad area PA1, and an area on which the third pads PD3 are disposed may be defined as a second pad area PA2.

The first pad area PA1 is an area to which the driving chip DC (see FIG. 4) is bonded, and the second pad area PA2 is an area to which the circuit board PB (see FIG. 4) is bonded. The first pad area PA1 may include a first area B1 on which the first pads PD1 are disposed and a second area B2 on which the second pads PD2 are disposed. The first pad area PA1 and the second pad area PA2 may be disposed in the non-display area DP-NDA. The first pad area PA1 and the second pad area PA2 may be spaced apart from each other in a first direction DR1. The first pad area PA1 may be an area adjacent to the display area DP-DA compared to the second pad area PA2, and the second pad area PA2 may be an area spaced apart from the display area DP-DA, and the first pad area PA1 is disposed between the second pad area PA2 and the display area DP-DA. Although a single row of pads is illustrated in the first pad area PA1, it is not limited thereto, and a plurality of pad rows may be disposed in the first pad area PA1.

In embodiments, the first pad area PA1 may include the pad structure according to embodiments configured to improve electrical connection and bonding reliability with the driving chip DC. For example, the first pads PD1 disposed in the first area B1 may be implemented with an insulating layer in which multiple openings are defined to expose portions of a second pad of the driving chip DC. A contact electrode disposed on the insulating layer may be electrically connected to the second pad through these openings, allowing conductive particles within an adhesive layer, or a conductive pattern on the display panel DP, to form multiple contact points with the contact electrode. This configuration can maintain stable electrical connectivity even when minor alignment deviations occur between the first pad area PA1 and the driving chip DC.

Each of the first pads PD1 may be connected to a corresponding one of the data lines DL. In an embodiment, the first pads PD1 and the second pads PD2 may be electrically connected to each other. The second pads PD2 may be connected to the third pads PD3 through connection signal lines S-CL.

In embodiments, by connecting each first pad PD1 to a corresponding data line DL and interconnecting the first pads PD1 with the second pads PD2, the arrangement allows signals to pass through a bonding interface that benefits from the increased contact area provided by the multiple-opening pad structure. The resulting electrical pathway may be less susceptible to open defects caused by incomplete particle contact, thereby supporting high-yield manufacturing and stable display performance.

The circuit board PB may include a plurality of circuit pads PB-PD. The circuit pads PB-PD may be arranged in the second direction DR2. The circuit pads PB-PD of the circuit board PB may be in contact with and connected to the third pads PD3 in the second pad area PA2.

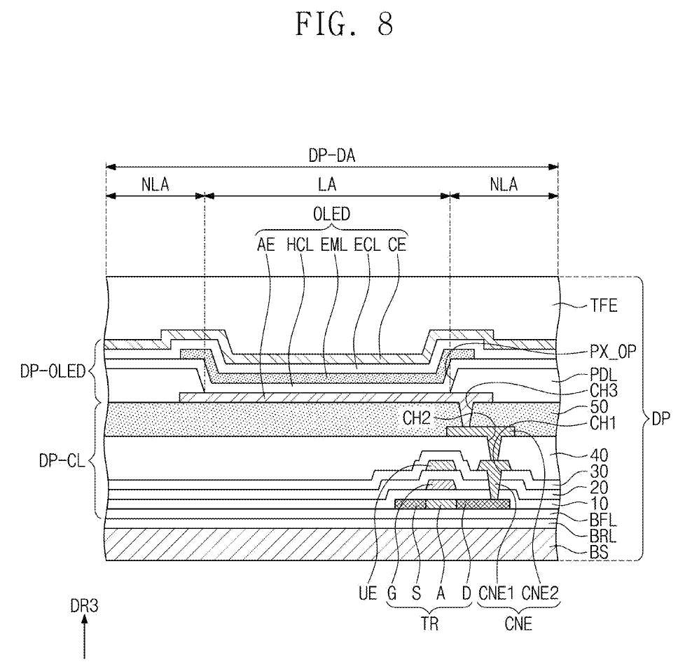

FIG. 8 is a cross-sectional view of the display panel DP according to an embodiment of the inventive concept.

Referring to FIG. 8, the display area DP-DA may include an emission area LA corresponding to each of the pixels PX (see FIG. 7) and a non-emission area NLA around the emission area LA. Each of the pixels PX (see FIG. 7) may include the light-emitting elements OLED and a driving circuit connected to the light-emitting element OLED. For example, the pixel PX (see FIG. 7) may include a transistor TR and a light-emitting element OLED.

In embodiments, at least a portion of the non-emission area NLA may include the first pad area PA1, which is configured for electrical connection to the driving chip DC. As described in detail below, the first pad area PA1 may incorporate a pad and insulating layer structure having multiple openings to expose portions of a corresponding pad of the driving chip DC. This configuration may allow a contact electrode to interface through the openings with conductive particles in an adhesive layer, or with a conductive pattern on the display panel DP, thereby enabling a reliable bumpless connection in the non-display region of the panel.

Referring to FIG. 8, a plurality of insulating layers may be disposed on a top surface of the base layer BS. The plurality of insulating layers may include a barrier layer BRL and a buffer layer BFL. The plurality of insulating layers may include first to fifth insulating layers 10 to 50. The barrier layer BRL may prevent foreign substances from entering into the device. The barrier layer BRL may include a silicon oxide layer and a silicon nitride layer. Each of the barrier layer BRL may be provided in plurality, and the silicon oxide layers and the silicon nitride layers may be alternately laminated.

The buffer layer BFL may improve adhesion force between the base layer BS and a semiconductor pattern and/or a conductive pattern. The buffer layer BFL may include a silicon oxide layer and a silicon nitride layer. The silicon oxide layer and the silicon nitride layer may be alternately laminated.

A semiconductor pattern may be provided on the buffer layer BFL. The semiconductor pattern may include, for example, polysilicon, amorphous or crystalline silicon, or a metal oxide. In FIG. 8, only a portion of the semiconductor pattern is illustrated, and additional semiconductor patterns may be provided in other areas of the display panel DP in a planar view. The semiconductor pattern may be doped with N-type dopants or P-type dopants. The semiconductor pattern may include a high-doped region and a low-doped region. A conductivity of a highly doped region may be greater than that of a low-doped region, and the highly doped region may substantially serve as source and drain electrodes of the transistor TR. The low-doped region may effectively correspond to an active region (or channel) of the transistor TR.

A drain region D, an active region A, and a source region S may be disposed on the buffer layer BFL. The drain region D, the active region A, and the source region S may define the transistor TR together with a gate G, which will be described further below. When the display panel DP includes a transistor other than the transistor TR, the other transistor may include a material different from that of the transistor TR and may be disposed on a different layer. The source region S, the active region A, and the drain region D of the transistor TR may be provided from the semiconductor pattern.

A first insulating layer 10 may be disposed on the buffer layer BFL. The first insulating layer 10 may cover the semiconductor pattern. A gate G of the transistor TR may be disposed on the first insulating layer 10. A second insulating layer 20 may be disposed on the gate G The gate G may be a portion of a metal pattern. The gate G may overlap the active region A. The gate G may function as a mask during a doping process for the semiconductor pattern.

The gate G may include, for example, titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), or the like, but is not particularly limited thereto.

The second insulating layer 20 covering the gate G may be disposed on the first insulating layer 10. The transistor TR according to an embodiment may further include an upper electrode UE disposed on the second insulating layer 20 and overlapping the gate G. A third insulating layer 30 may be disposed on the second insulating layer 20. The first to third insulating layers 10 to 30 may be an inorganic layer and/or an organic layer and may have a single-layer or multi-layer structure.

A connection electrode CNE may include a first connection electrode CNE1 and a second connection electrode CNE2 to connect the transistor TR and the light-emitting element OLED. A first connection electrode CNE1 may be disposed on the third insulating layer 30 and may be connected to the drain region D through a first contact hole CH1 defined in the first to third insulating layers 10 to 30.

A fourth insulating layer 40 may be disposed on the third insulating layer 30. The fourth insulating layer 40 may be an organic layer. A second connection electrode CNE2 may be disposed on the fourth insulating layer 40. The second connection electrode CNE2 may be connected to the first connection electrode CNE1 through a second contact hole CH2 defined in the fourth insulating layer 40.

A fifth insulating layer 50 may be disposed on the second connection electrode CNE2. Layers from the buffer layer BFL to the fifth insulating layer 50 may be defined as the circuit element layer DP-CL. The fifth insulating layer 50 may be an organic layer. A first electrode AE may be disposed on the fifth insulating layer 50. The first electrode AE may be connected to the second connection electrode CNE2 through a third contact hole CH3 defined in the fifth insulating layer 50. The first electrode AE may be connected to the transistor TR via the first and second connection electrodes CNE1 and CNE2. A pixel defining layer PDL in which an opening PX_OP is defined to expose a predetermined portion of the first electrode AE may be disposed on the first electrode AE and the fifth insulating layer 50.

The hole control layer HCL may be disposed on the first electrode AE and the pixel defining layer PDL. The hole control layer HCL may include a hole transport layer and a hole injection layer.

The emission layer EML may be disposed on the hole control layer HCL. The emission layer EML may be disposed in an area corresponding to the opening OP. The emission layer EML may include organic and/or inorganic materials. The emission layer EML may emit one of red light, green light, and blue light.

The electron control layer ECL may be disposed on the emission layer EML and the hole control layer HCL. The electron control layer ECL may include an electron transport layer and an electron injection layer. The hole control layer HCL and the electron control layer ECL may be commonly disposed in the emission area LA and the non-emission area NLA.

The second electrode CE may be disposed on the electronic control layer ECL. The second electrode CE may be commonly disposed for the pixels PX (see FIG. 7). The layer on which the light-emitting element OLED is disposed may be defined as the display element layer DP-OLED.

The thin film encapsulation layer TFE may be disposed on the second electrode CE to cover the pixel PX (see FIG. 7). In an embodiment, the thin-film encapsulation layer TFE may be provided in multi-layer structure. A portion of the multiple layers may include an inorganic layer and protect the pixels PX (see FIG. 7) from moisture or oxygen. The remaining layers may include an organic layer and protect the pixels PX (see FIG. 7) from foreign substances such as dust.

In the non-display area DP-NDA, the thin-film encapsulation layer TFE may be patterned or dimensioned to accommodate the height and arrangement of the pad structure according to embodiments, facilitating the bonding of the display panel DP to the driving chip DC without the use of protruding bumps.

A first voltage may be applied to the first electrode AE through the transistor TR, and a second voltage having a lower level than the first voltage may be applied to the second electrode CE. A hole and an electron injected into the light emitting layer EML are coupled to each other to form an exciton, and while the exciton is transited to a ground state, the light-emitting element OLED may emit light.

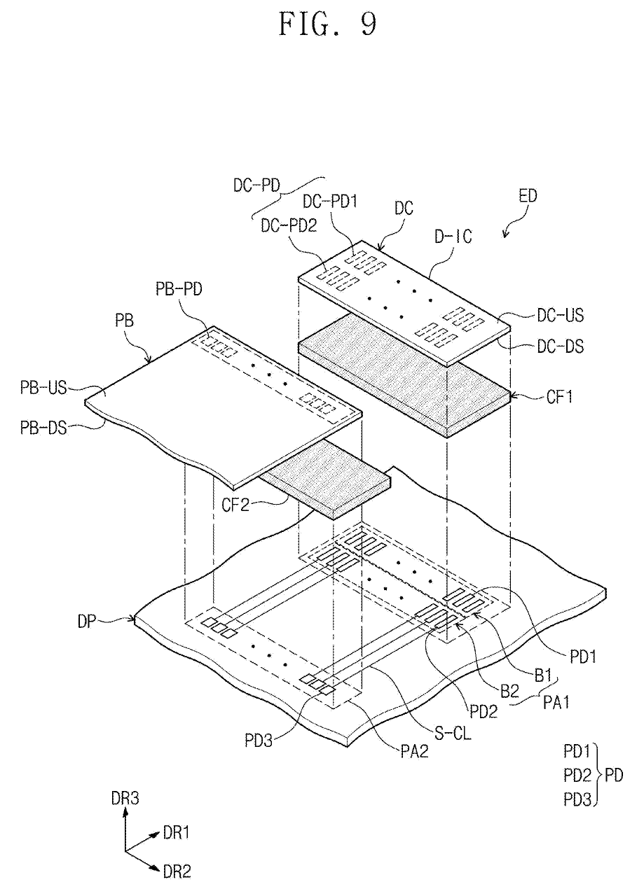

FIG. 9 is an enlarged and exploded perspective view illustrating pad areas PA1 and PA2 of an electronic device ED according to an embodiment of the inventive concept. For example, in FIG. 9, the driving chip DC and the circuit board PB are illustrated as separated from the display panel DP. The first pads PD1, the second pads PD2, the connection signal lines S-CL, and the third pads PD3 shown in FIG. 9 are the same as those shown in FIG. 7, and thus a detailed description thereof may be omitted.

The driving chip DC may be bonded to the first pad area PA1 through a first adhesive layer CF1, and the circuit board PB may be bonded to the second pad area PA2 through a second adhesive layer CF2.

In embodiments, the first pad area PA1 may include an insulating layer having a plurality of openings that partially expose a surface of each first pad PD1. A contact electrode may be disposed to overlap the openings, such that, when the first adhesive layer CF1 is interposed between the first pad area PA1 and the driving chip DC, conductive particles within the adhesive resin (in the case of an anisotropic conductive film) or a conductive pattern on the display panel DP may contact the exposed regions of the first pads PD1 through the openings. This structure may allow the driving chip DC to be electrically connected to the first pads PD1 without requiring protruding bumps on a first driving pads DC-PD1, thereby enabling a bumpless bonding configuration.

According to an embodiment of the inventive concept, each of the first adhesive layer CF1 and the second adhesive layer CF2 may be an anisotropic conductive film (ACF). For example, the first adhesive layer CF1 and the second adhesive layer CF2 may include an adhesive resin and conductive particles dispersed in the adhesive resin.

According to an embodiment of the inventive concept, each of the first adhesive layer CF1 and the second adhesive layer CF2 may be a non-conductive film. For example, each of the first adhesive layer CF1 and the second adhesive layer CF2 may not include a conductive ball and may include a synthetic resin having adhesiveness. Since the synthetic resin does not need to maintain an arrangement of the conductive balls, the synthetic resin may have a relatively low viscosity compared to the adhesive resin. However, the inventive concept is not limited thereto, and in an embodiment, either the first adhesive layer CF1 or the second adhesive layer CF2 may be omitted for example, each of the driving chip DC and the circuit board PB may be bonded to the first pad area PA1 and the second pad area PA2 by ultrasonic bonding.

When the first adhesive layer CF1 is implemented as a non-conductive film, the multiple-opening insulating layer in the first pad area PA1 may facilitate penetration of the adhesive resin into the openings and direct contact between the contact electrode and the exposed regions of the first pads PD1. In both the anisotropic conductive film and non-conductive film cases, the distribution of multiple openings may reduce localized bonding stress and helps maintain consistent pad height across the first pad area PA1, thereby improving bonding reliability and alignment accuracy between the display panel DP and the driving chip DC.

The driving chip DC may include a driving integrated circuit D-IC and a driving pad DC-PD. The driving integrated circuit D-IC may include a top surface DC-US and a bottom surface DC-DS, and the bottom surface DC-DS may be a surface facing the first pads PD1 and the second pads PD2. The driving pad DC-PD may be disposed on the bottom surface DC-DS of the driving integrated circuit D-IC.

The driving pads DC-PD may include first driving pads DC-PD1 electrically connected to the respective first pads PD1 and second driving pads DC-PD2 electrically connected to the respective second pads PD2. The first driving pads DC-PD1 may be arranged along a second direction DR2, and the second driving pads DC-PD2 may be spaced apart from the first driving pads DC-PD1 in a first direction DR1 and may be arranged along the second direction DR2.

The driving chip DC may receive first signals from outside of the driving chip DC through the second pads PD2 and the second driving pads DC-PD2. The driving chip DC may provide second signals, which are generated based on the first signals, to the first pads PD1 through the first driving pads DC-PD1. For example, the driving chip DC may include a data driving circuit. The first signal may be a video signal, which is a digital signal applied from outside of the driving chip DC, and the second signal may be a data signal, which is an analog signal. The driving chip DC may generate an analog voltage corresponding to a gray scale value of an image signal. A data signal may be provided to the pixel PX through the data line DL as illustrated in FIG. 6.

When the first adhesive layer CF1 is cured, the first pads PD1 and the first driving pads DC-PD1 may be fixed in a state of being in contact with each other, and the second pads PD2 and the second driving pads DC-PD2 may also be fixed in a state of being in contact with each other.

By eliminating the need for bumps on the driving pads DC-PD1 and DC-PD2, the bonding configuration according to embodiments can reduce manufacturing complexity, improve yield, and reduce the risk of pad or chip damage during bonding. The bumpless configuration also allows a thinner overall profile in the bonded region, which can aid in achieving a reduced bezel size in the electronic device ED.

The circuit board PB may include circuit pads PB-PD. The circuit board PB may include a top surface PB-US and a bottom surface PB-DS, and the bottom surface PB-DS may be a surface facing the third pads PD3. The circuit pads PB-PD may be disposed on the bottom surface PB-DS of the circuit board PB. The circuit pads PB-PD may be electrically connected to the third pads PD3, respectively. The circuit pads PB-PD may be arranged along the second direction DR2. The circuit board PB may provide an image signal, a driving voltage, and other control signals to the driving chip DC.

When the second adhesive layer CF2 is cured, the third pads PD3 and the circuit pads PB-PD may be fixed in a state of being in contact with each other.

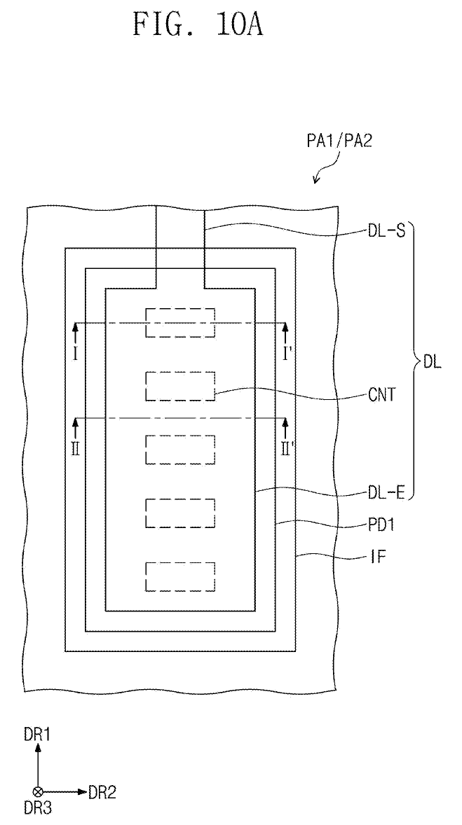

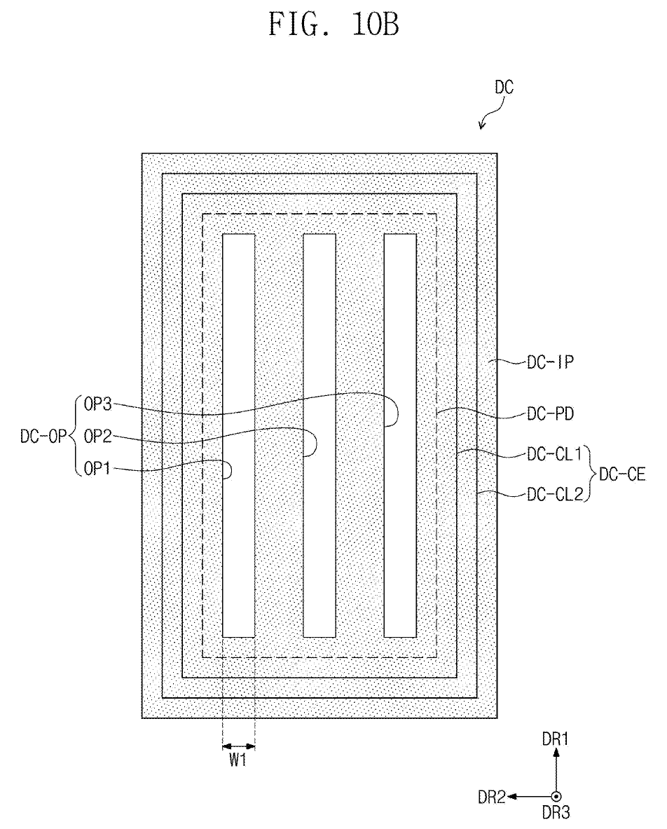

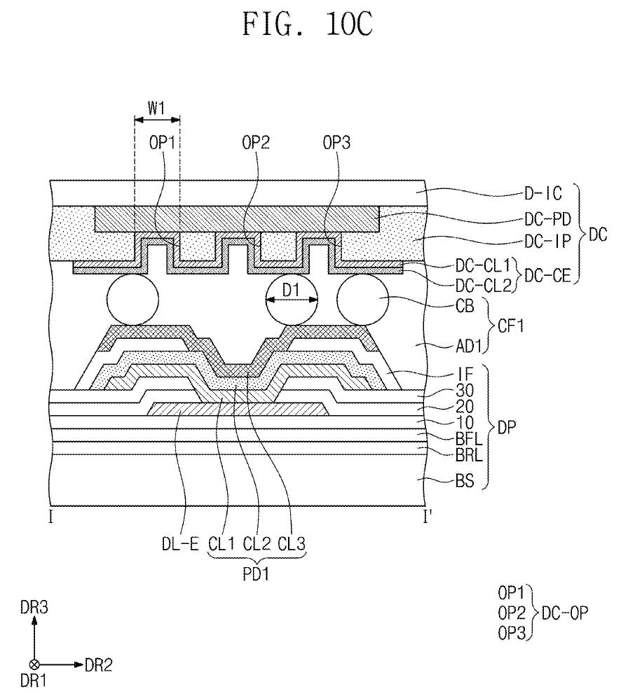

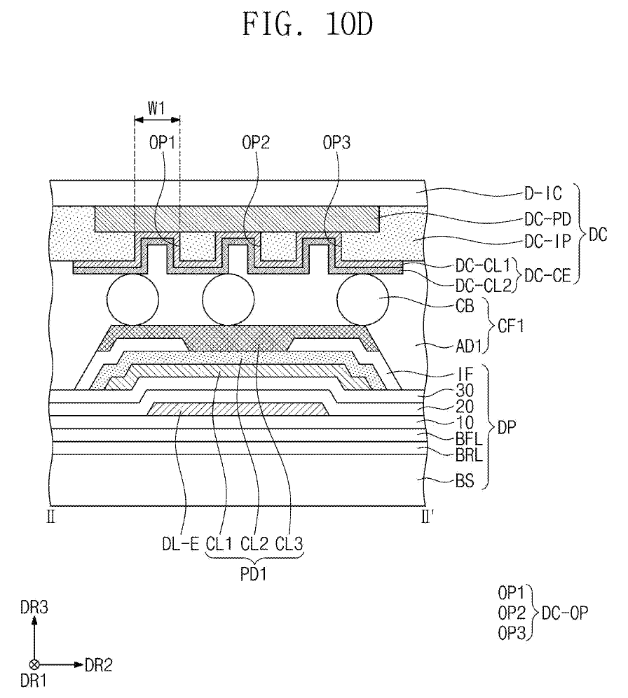

FIG. 10A is a plan view illustrating the pad area of the display panel according to an embodiment of the inventive concept. FIG. 10B is a plan view of the pad area of the driving chip DC according to an embodiment of the inventive concept. FIGS. 10C and 10D are cross-sectional views illustrating the pad area of the electronic device according to an embodiment of the inventive concept, respectively. FIG. 10C is a cross-sectional view taken along line I–I' of FIG. 10A, and FIG. 10D is a cross-sectional view taken along line II–II' of FIG. 10A.

FIG. 10A illustrates an example of a plan view showing the first pad area PA1 of the electronic device ED in which the display panel DP and the driving chip DC shown in FIG. 9 are bonded. The description of FIG. 10A may be applied to a plan view of the second pad area PA2, to which the circuit board PB is bonded instead of the driving chip DC.

Referring to FIG. 10A, the data line DL may include a line portion DL-S and an end portion DL-E. The line portion DL-S may be connected to a corresponding pixel PX and may extend in the first direction DR1. In FIG. 10A, as an example, the end portion DL-E and the line portion DL-S having different widths are illustrated, but the inventive concept is not limited thereto. Here, the width may refer to a length or width in the second direction DR2 of the end portion DL-E or the line portion DL-S. The end portion DL-E of the data line DL may extend in the first direction DR1 from a terminal edge of the line portion DL-S.

In a planar view, the first pad PD1 may overlap the end portion DL-E of the data line DL and may be connected to the data line DL through a contact hole CNT provided inside the first pad PD1. A plurality of contact holes CNT may be provided, and the plurality of contact holes CNT may be spaced apart from each other in the first direction DR1.

In a planar view, an insulating layer IF of the input sensor ISU (see FIG. 6) may be disposed outside the first pad PD1. The insulating layer IF may refer to a base layer IL1 (see FIG. 6), a first sensing insulating layer IL2, and a second sensing insulating layer IL3 laminated in the input sensor ISU (see FIG. 6).

FIG. 10B is a plan view of the pad area of the driving chip DC corresponding to the pad area PA1 of FIG. 10A. Referring to FIGS. 10B and 10C, the driving chip DC may include a driving pad DC-PD1 corresponding to the first pad PD1 of FIG. 10A. The driving chip DC may include a driving integrated circuit D-IC, a driving pad DC-PD1 electrically connected to the driving integrated circuit D-IC, an insulating layer DC-IP in which a plurality of openings DC-OP exposing a portion of the driving pad DC-PD1 are defined, and a contact electrode DC-CE disposed on the insulating layer DC-IP and electrically connected to the driving pad DC-PD1 through the plurality of openings DC-OP.

In an embodiment, the contact electrode DC-CE may include a multilayer structure. For example, the contact electrode DC-CE may include a first metal layer DC-CL1 directly disposed on the driving pad DC-PD1, and a second metal layer DC-CL2 disposed on the first metal layer DC-CL1. The contact electrode DC-CE may be disposed inside the plurality of openings DC-OP and may cover the openings DC-OP. The first metal layer DC-CL1 may be in contact with the driving pad DC-PD exposed by the openings DC-OP and may be electrically connected to the driving pad DC-PD. The second metal layer DC-CL2 may be in contact with the first metal layer DC-CL1, and may be in contact with conductive balls CB, thereby electrically connected to the display panel DP.

The first metal layer DC-CL1 may include at least one of, for example, titanium (Ti), tungsten (W), and titanium–tungsten (TiW) alloy, so that adhesion between the first metal layer DC-CL1 and the driving pad DC-PD1 may be improved. The second metal layer DC-CL2 may include at least one of, for example, silver (Ag), palladium (Pd), and gold (Au), so that electrical conductivity with the conductive balls CB may be improved.

Referring to FIG. 10B, in a planar view, the driving pad DC-PD1 may correspond to the first pad PD1 of the display panel (see FIG. 10A) and may extend in the first direction DR1. In a planar view, the plurality of openings DC-OP may be provided inside the driving pad DC-PD1. The plurality of openings DC-OP may include a first opening OP1, a second opening OP2, and a third opening OP3.

In an embodiment, each of the first opening OP1, the second opening OP2, and the third opening OP3 may have a shape extending in the first direction DR1. For example, the first opening OP1, the second opening OP2, and the third opening OP3 may each have a rectangular shape extending in the first direction DR1. Each of the first opening OP1, the second opening OP2, and the third opening OP3 may have a rectangular shape, of which a length in the first direction DR1 is greater than a length W1 in the second direction DR2. Each of the first opening OP1, the second opening OP2, and the third opening OP3 may be spaced apart from each other in the second direction DR2.

Referring to FIGS. 10A to 10C, the length W1 in the second direction DR2 of each of the plurality of openings DC-OP may be smaller than a diameter D1 of the conductive ball CB. For example, the length W1 of the second direction DR2 of each of the plurality of openings DC-OP may be in the range of about 1μm to about 3μm. A diameter D1 of a conductive ball CB may be greater than about 3μm. Accordingly, the conductive ball CB may be inserted into the plurality of openings DC-OP without being in contact therewith. The conductive ball CB may be in contact with a contact electrode DC-CE disposed on an insulating layer DC-IP. As contact points and a contact area between the conductive ball CB and the contact electrode DC-CE increase, bonding reliability of the electronic device may be improved.

In embodiments, the elongated openings OP1 to OP3 may also serve to relax alignment tolerances between the conductive balls CB and the driving pads DC-PD. Even when a conductive ball CB is partially misaligned relative to a driving pad DC-PD, the elongation of the opening in the first direction DR1 may increase the probability of electrical connection while maintaining the same pad footprint. This configuration may also promote a more uniform distribution of bonding force during compression, reducing localized stress concentrations and thereby enhancing mechanical bonding reliability over extended operational lifetimes.

Referring to FIG. 10C, in an embodiment, the driving chip DC does not include a bump protruding from the contact electrode DC-CE. That is, according to embodiments of the inventive concept, bumpless electronic components in which bumps of the driving chip DC is omitted may be bonded to each other. Since the driving chip does not include the bump, a manufacturing process for the electronic device may be simplified.

In addition, according to embodiments, by omitting bumps on the driving chip DC, overall module thickness may be reduced, which can aid in the formation of thin-profile display devices. The elimination of bumps may simplify the manufacturing process, reduce the number of photolithography and electroplating steps, and lower material usage. Furthermore, in the absence of bumps, parasitic capacitance between the driving chip DC and the first pads PD1 on the display panel DP can be reduced, thereby improving high-frequency signal integrity and potentially lowering power consumption during high-speed data transmission.

Referring to FIGS. 10A to 10C, the end portion DL-E of the data line may be disposed on the first insulating layer 10. The end portion DL-E may be disposed on the same layer as the gate G (See FIG. 8) of the transistor TR (see FIG. 8). That is, the data line may be manufactured through the same process as the gate G (see FIG. 8) and may include the same material as the gate G.

The first pad PD1 may include a first conductive pattern CL1, a second conductive pattern CL2 disposed on the first conductive pattern CL1, and a third conductive pattern CL3 disposed on the second conductive pattern CL2.

The first conductive pattern CL1 may be connected to the end portion DL-E through the contact hole CNT. The first conductive pattern CL1 may be disposed on the third insulating layer 30 exposed through the contact hole CNT, and may be disposed on the same layer as the first connection electrode CNE1 (see FIG. 8). That is, the first conductive pattern CL1 may be provided through the same process as the first connection electrode CNE1 (see FIG. 8) and may include the same material as the first connection electrode CNE1.

In addition, the second conductive pattern CL2 may be disposed on the first conductive pattern CL1 and be in contact with the first conductive pattern CL1. The second conductive pattern CL2 may be provided through the same process as one of conductive electrodes in the circuit element layer DP-CL (see FIG. 8). For example, the second conductive pattern CL2 may be provided through the same process as the second connection electrode CNE2 (see FIG. 8) and may include the same material as the second conductive pattern CL2. That is, the fourth insulating layer 40 (see FIG. 8) may be further included between the second conductive pattern CL2 and the first conductive pattern CL1.

The third conductive pattern CL3 may be disposed on the second conductive pattern CL2 and be in contact with the second conductive pattern CL2. The third conductive pattern CL3 may be disposed on an insulating layer IF exposed by the contact hole. The third conductive pattern CL3 may be provided through the same process as any one of conductive layers of the input sensor ISU (see FIG. 6). For example, the third conductive pattern CL3 may be provided through the same process as the first sensing conductive layer SCL1 or the second sensing conductive layer SCL2 and may be provided using the same material as the first sensing conductive layer SCL1 and the second sensing conductive layer SCL2.

Referring to FIGS. 10A to 10D, FIG. 10D is a cross-sectional view of a portion of the pad area on which the contact hole CNT of FIG. 10A is not provided. The first pad PD1 in FIG. 10D may not be directly electrically connected to the end portion DL-E of the data line. However, since the first pad PD1 and the end portion DL-E in FIG. 10C are connected through the contact hole CNT, the first pad PD1 and the end portion DL-E in FIG. 10D may be indirectly connected. As shown in FIG. 10D, the conductive ball CB may be in contact with a second metal layer DC-CL2 disposed between the plurality of openings DC-OP and the third conductive pattern CL3 positioned on an uppermost surface of the first pad PD1. Accordingly, an increase in the contact area between the conductive ball CB and the third conductive pattern CL3 may lead to improved electrical characteristics. Accordingly, the plurality of openings DC-OP may increase the number of contact points between the conductive balls CB and the third conductive pattern CL3, thereby reducing open defects caused by incomplete contact between the driving chip DC and the display panel DP.

Furthermore, according to embodiments, forming the third conductive pattern CL3 through a process also used for the input sensor electrodes may promote material and process compatibility across different functional regions of the display device. This compatibility can lead to improved uniformity of electrical characteristics between conductive interfaces, reduced contact resistance variation across the pad array, and enhanced long-term stability under environmental stresses such as thermal cycling and humidity exposure. As a result, the pad structures described herein may contribute not only to immediate bonding performance but also to the maintenance of low-resistance, stable electrical connections over the product’s operational lifetime.

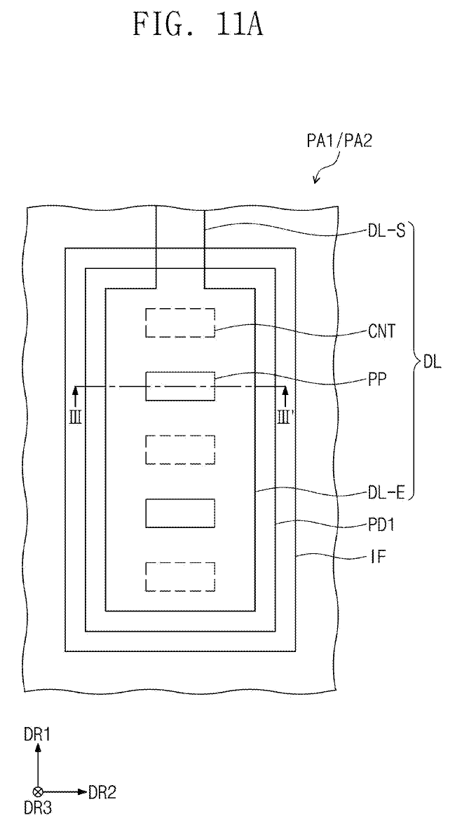

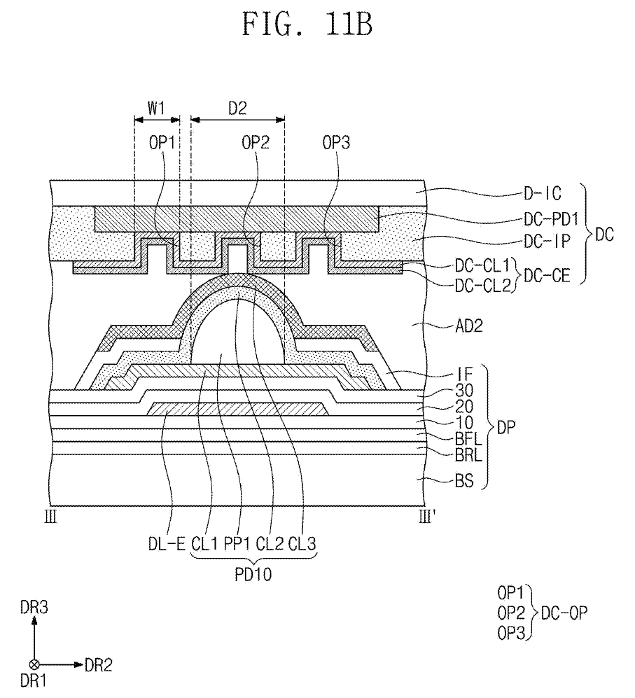

FIG. 11A is a plan view illustrating a pad area of a display panel according to an embodiment of the inventive concept. FIG. 11B is a cross-sectional view illustrating a pad area of an electronic device according to an embodiment of the inventive concept. FIG. 11B is a cross-sectional view taken along line III–III' of FIG. 11A.

Each of FIG. 11A and FIG. 11B illustrates a case in which conductive balls CB are not included in adhesive layers of FIGS. 10A to 10D, and the driving chip DC and the display panel DP are directly in contact with each other through a polymer pattern PP.

Referring to FIG. 11A, the polymer pattern PP may be disposed between a plurality of contact holes CNT spaced apart in the first direction DR1. A plurality of polymer patterns PP may be provided, and the plurality of polymer patterns PP may be disposed between adjacent contact holes CNT in the first direction DR1.

Referring to FIG. 11B, a first pad PD10 may further include the polymer pattern PP disposed between a first conductive pattern CL1 and a second conductive pattern CL2. The polymer pattern PP may be disposed on the first conductive pattern CL1 and may be covered by the second conductive pattern CL2. The polymer pattern PP may overlap a portion of the first conductive pattern CL1. The polymer pattern PP may define a protrusion in a thickness direction of the display panel DP. The polymer pattern PP may include not only a polymer and further include a material including an insulating property and capable of defining the protrusion.

In embodiments, the height and material properties of the polymer pattern PP may be selected to maintain a consistent contact pressure between the third conductive pattern CL3 and the contact electrode DC-CE, even when the display panel DP undergoes thermal expansion or mechanical stress during assembly. The protruding profile of the polymer pattern PP may also act as a micro-alignment guide, reducing the risk of lateral slippage during bonding and further improving yield.

The second conductive pattern CL2 may be in contact with a portion of the first conductive pattern CL1, which is not covered by the polymer pattern PP, and a third conductive pattern CL3 may be electrically connected to the first conductive pattern CL1 through the second conductive pattern CL2.

The third conductive pattern CL3 disposed to overlap the polymer pattern PP may be in direct contact with a contact electrode DC-CE of the driving chip DC. That is, the third conductive pattern CL3 may be in contact with the contact electrode DC-CE through the plurality of openings DC-OP of the driving chip DC, and may be electrically connected to a driving pad DC-PD. Even if alignment deviation occurs such that the first pad PD10 is shifted in a second direction DR2 with respect to the driving chip DC, the third conductive pattern CL3 and the contact electrode DC-CE may still be uniformly in contact with each other. Accordingly, a bonding gap defined by a bonding distance variation between the driving chip DC and the display panel DP may be reduced. That is, a bonding non-uniformity issue caused by alignment deviation may be resolved, and bonding reliability may be increased.

By providing that the third conductive pattern CL3 remains in reliable contact with the contact electrode DC-CE despite alignment deviations in the second direction DR2, the disclosed configuration according to embodiments may reduce susceptibility to open-circuit defects in high-density pad arrays, which may aid in the design and implementation of narrow-bezel or high-resolution displays, where pad pitch reduction can exacerbate misalignment sensitivity. The overlap between the third conductive pattern CL3 and the polymer pattern PP can also serve to distribute bonding stress more evenly, mitigating localized strain concentrations.

In an embodiment, a length W1 in the second direction DR2 of each of the plurality of openings DC-OP may be smaller than a length D2 in the second direction DR2 of the polymer pattern PP. The length in the second direction DR2 of the polymer pattern PP may be defined as a maximum distance in the second direction DR2 of the polymer pattern PP in contact with the first conductive pattern CL1. Accordingly, the third conductive pattern CL3 disposed on the polymer pattern PP may be in point contact with a contact electrode DC-CE disposed in an insulating layer DC-IP between the plurality of openings DC-OP. For example, the first conductive pattern CL1 may include titanium (Ti), the second conductive pattern CL2 may include aluminum (Al), and the third conductive pattern CL3 may include titanium (Ti). Since the third conductive pattern CL3 is in point contact with the contact electrode DC-CE, the third conductive pattern CL3 may undergo tensile cracking, and the second conductive pattern CL2 may be partially exposed. That is, the second conductive pattern CL2 including aluminum (Al) may be substantially connected to a second metal layer DC-CL2, so that electrical resistance may be reduced and bonding reliability may be improved.

In embodiments, the dimensional relationship between the openings DC-OP and the polymer pattern PP may be configured such that point contact occurs at multiple discrete regions, providing redundant electrical paths. This redundancy can improve long-term reliability in environments subject to vibration or repeated thermal cycling. Additionally, the use of dissimilar metals for the conductive patterns, for example, titanium for the first and third conductive patterns CL1 and CL3, and aluminum for the second conductive pattern CL2, may be selected to balance conductivity, adhesion strength, and corrosion resistance, further enhancing device durability.

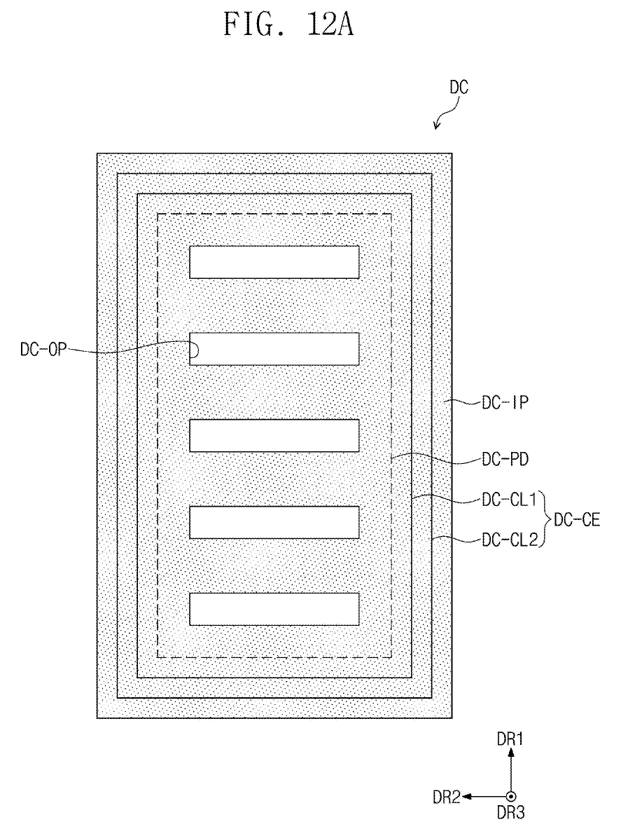

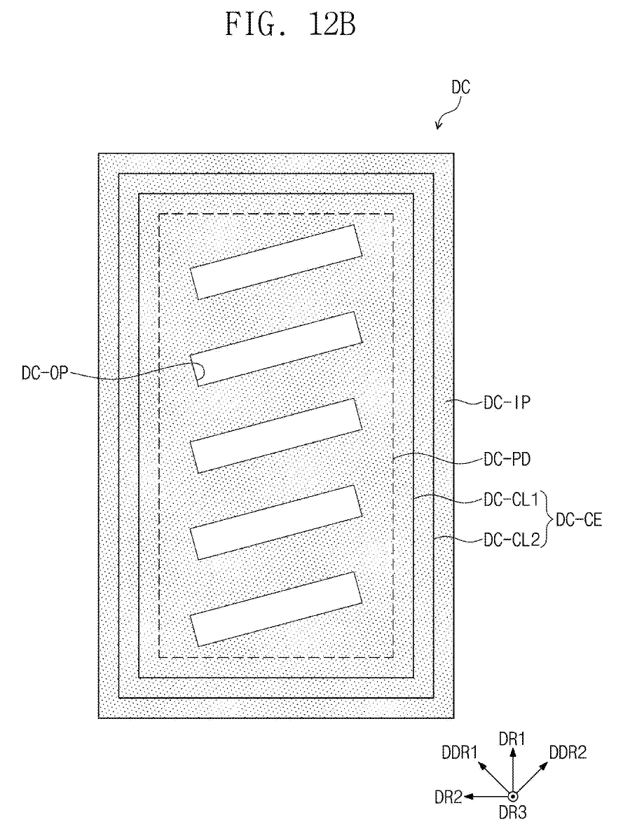

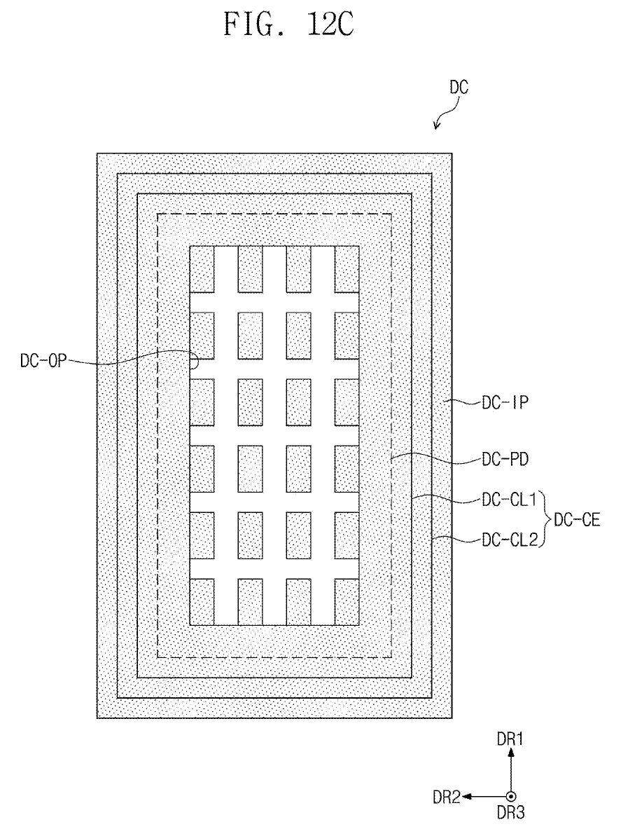

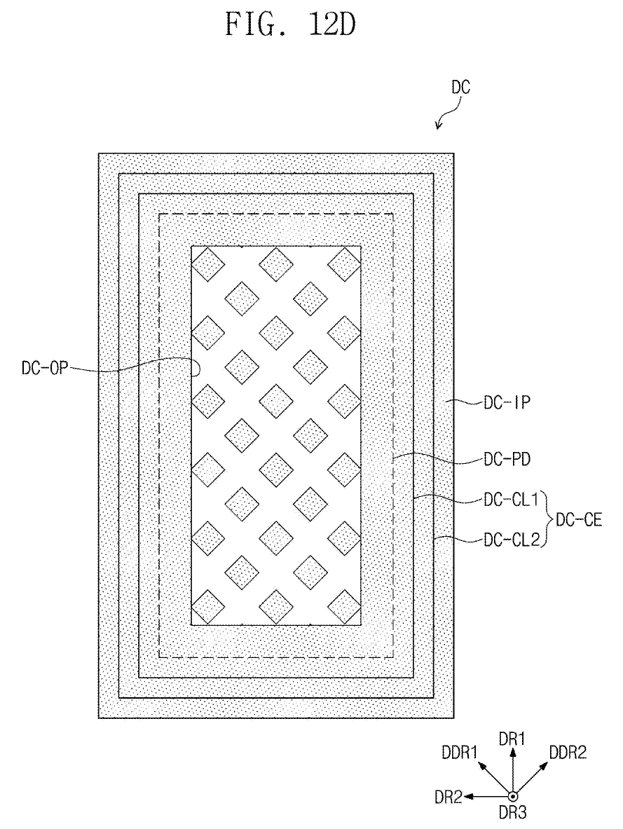

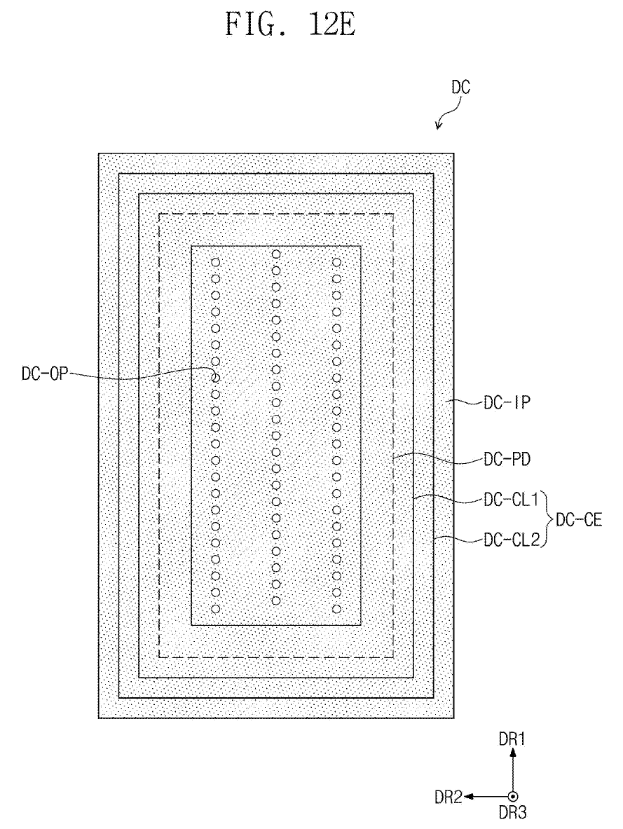

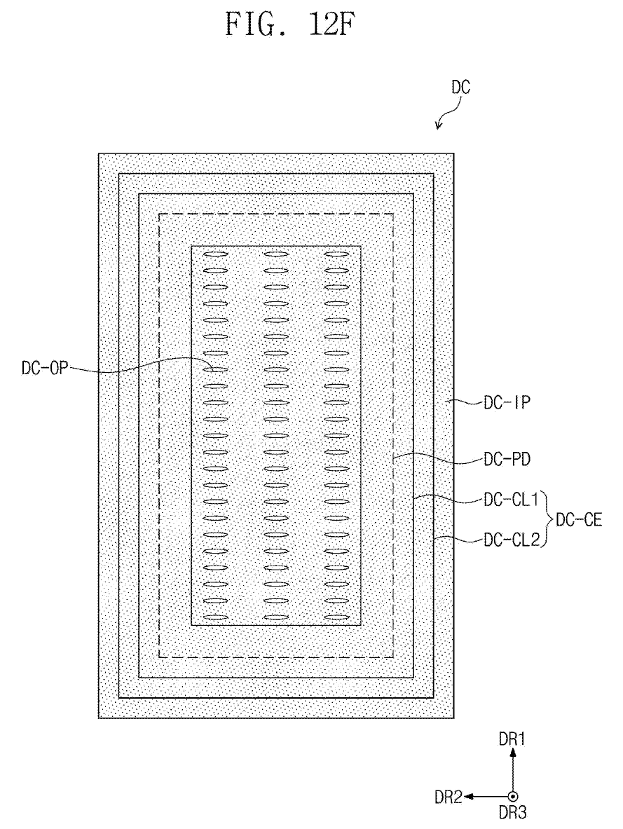

FIGS. 12A to 12F are plan views illustrating pad areas of driving chips according to an embodiments of the inventive concept, respectively. The configurations shown in FIGS. 12A to 12F may be applied in the same manner to each configuration of the driving chip DC shown in FIG. 10B, and the following description focuses on differences from FIG. 10B. In the openings DC-OP shown in FIGS. 12A to 12F, some of the openings DC-OP disposed at centers in a first direction DR1 may be omitted.

Referring to FIG. 12A, each of the plurality of openings DC-OP may extend in the second direction DR2 and may be spaced apart from each other in the first direction DR1. That is, each of the plurality of openings DC-OP may have a rectangular shape with a length in the second direction DR2 greater than a length in the first direction DR1. A length of each of the plurality of openings DC-OP in the first direction DR1 may be smaller than a diameter D1 of a conductive ball CB (see FIG. 10C).

In embodiments, the elongated rectangular shape of the openings DC-OP may facilitate desired deformation or flow of bonding material along the second direction DR2 during thermal compression bonding, thereby enhancing wetting between the contact electrode DC-CE and the third conductive pattern CL3. This configuration can also help relieve localized stress caused by slight rotational misalignment, improving both electrical connection stability and mechanical durability.

Referring to FIG. 12B, a first diagonal direction DDR1 may be defined as a direction between the first direction DR1 and the second direction DR2, and a second diagonal direction DDR2 may be defined as a direction intersecting the first diagonal direction DDR1. Each of the plurality of openings DC-OP may extend in the second diagonal direction DDR2 and may be spaced apart from each other in the first diagonal direction DDR1. That is, each of the plurality of openings DC-OP in FIG. 12A may be spaced apart from each other in a diagonal direction. A length of each of the plurality of openings DC-OP in the first diagonal direction DDR1 may be smaller than the diameter D1 of the conductive ball CB (see FIG. 10C).

In embodiments, the diagonal arrangement of the openings DC-OP may distribute bonding pressure more evenly across the pad area, reducing the likelihood of partial non-contact regions. In high-density interconnect applications, such diagonal spacing can also increase the effective contact path length without enlarging the pad footprint, allowing for the implementation of narrow-bezel display designs.

Referring to FIG. 12C, the openings DC-OP may be provided as an integrated structure arranged in a matrix shape that defines a plurality of rows and a plurality of columns. That is, the matrix shape of the openings DC-OP in FIG. 12C may be a mesh-type structure arranged in a grid with rows and columns. An insulating layer DC-IP including spaced-apart patterns may be disposed between the integrated openings DC-OP.

The matrix-type integrated openings DC-OP according to embodiments can provide a high density of micro-contact points, which may improve current distribution and reduce contact resistance. Such a grid structure can also act as a physical anchor for conductive adhesive, mitigating delamination during thermal cycling or vibration exposure.

Referring to FIG. 12D, the openings DC-OP may be provided as an integrated structure arranged in a matrix shape defining rows in the first diagonal direction DDR1 and columns in the second diagonal direction DDR2. That is, the openings DC-OP of FIG. 12C may be arranged diagonally.

In embodiments, the diagonal matrix arrangement of the openings DC-OP may further enhance mechanical interlocking between bonded layers when compared to orthogonal grids, for example, in assemblies subject to shear forces. This configuration can improve resistance to pad lifting in cases of repeated flexing or impact.

Referring to FIGS. 12E and 12F, each of the plurality of openings DC-OP may have a circular or elliptical shape. As shown in FIG. 12E, each of the plurality of openings DC-OP may be in the shape of dots spaced apart from each other in the first direction DR1 and the second direction DR2. As shown in FIG. 12F, each of the plurality of openings DC-OP may be arranged in the shape of ellipses having a length in the first direction DR1 shorter than a length in the second direction DR2 and may be spaced apart in from each other the first and second directions. A length of each of the plurality of openings DC-OP in the first direction DR1 may be smaller than the diameter D1 of the conductive ball CB (see FIG. 10C), and a length in the second direction DR2 may also be smaller than the diameter D1 of the conductive ball CB (see FIG. 10C).

The dot-type and elliptical opening shapes may be selected to balance the trade-off between increasing conductive contact points and reducing stress concentration in the insulating layer DC-IP. Elliptical shapes oriented with the longer axis along the second direction DR2 can also help accommodate differential expansion between the driving chip DC and the display panel DP during temperature changes.

Accordingly, through the plurality of openings DC-OP, the contact area between the contact electrode DC-CE connected to the driving pad DC-PD and either the conductive ball CB (see FIG. 10C) or the third conductive pattern CL3 (see FIG. 11B) of the display panel DP may increase, thereby improving bonding reliability.

In addition to increasing contact area, the varied opening geometries described herein can be selected for different manufacturing tolerances and environmental conditions. For example, in applications in which high resistance to moisture ingress is a desired benefit, the arrangement of the openings DC-OP may be selected to promote uniform sealant coverage while still maintaining reliable electrical contact. Likewise, in displays intended for portable devices subject to mechanical shock, certain configurations can better absorb and dissipate bonding stresses, extending operational life.

According to embodiments of the inventive concept, the electronic component may include the plurality of openings that expose a portion of the pad and the contact electrode connected to the pad, and may be electrically connected to the display panel. Through the plurality of openings, the contact area between the contact electrode and the conductive balls in the adhesive layer may be increased, thereby improving bonding reliability. In addition, the plurality of openings of the electronic component may be directly connected to the pad of the display panel. Since the electronic component is connected to the display panel through the plurality of openings, uniform bonding may be achieved even in the presence of misalignment of the pad of the display panel.

As is traditional in the field of the inventive concept, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. In embodiments, each block, unit and/or module may be implemented by dedicated hardware, or as a combination of dedicated hardware to perform some functions and a processor (e.g., one or more programmed microprocessors and associated circuitry) to perform other functions.

While the inventive concept has been particularly shown and described with reference to embodiments thereof, it will be understood by those of ordinary skill in the art that various changes in form and detail may be made therein without departing from the spirit and scope of the inventive concept as defined by the following claims.

What is claimed is:

1. An electronic device, comprising:
a display panel comprising a first pad;
an electronic component electrically connected to the display panel;
an adhesive layer configured to bond the display panel and the electronic component to each other; and
a conductive particle disposed in the adhesive layer and configured to electrically connect the display panel and the electronic component to each other,
wherein the electronic component comprises:
a second pad;
an insulating layer in which a plurality of openings exposing a portion of the second pad are defined; and
a contact electrode disposed on the insulating layer and connected to the second pad through the plurality of openings.

2. The electronic device of claim 1, wherein, in a plan view, the second pad extends in a first direction, and each of the plurality of openings extends along the first direction.

3. The electronic device of claim 2, wherein a length of each of the plurality of openings in a second direction intersecting the first direction is smaller than a diameter of the conductive particle.

4. The electronic device of claim 2, wherein the plurality of openings are spaced apart from each other in a second direction intersecting the first direction.

5. The electronic device of claim 2, wherein a length of each of the plurality of openings in the first direction is greater than a length in a second direction intersecting the first direction.

6. The electronic device of claim 1, wherein the contact electrode comprises:
a first metal layer directly disposed on the second pad; and
a second metal layer disposed on the first metal layer,
wherein the first metal layer comprises titanium–tungsten (TiW) alloy, and the second metal layer comprises gold (Au).

7. The electronic device of claim 1, wherein the electronic component is a driving chip.

8. The electronic device of claim 1, wherein the electronic component does not include a bump protruding from the contact electrode.

9. The electronic device of claim 1, wherein, in a plan view,
the second pad extends in a first direction,
each of the plurality of openings extends in a second direction intersecting the first direction,
the plurality of openings is spaced apart from each other in the first direction, and
a length of each of the plurality of openings in the first direction is smaller than a diameter of the conductive particle.

10. The electronic device of claim 1, wherein, in a plan view,
the second pad extends in a first direction,
each of the plurality of openings extends in a first diagonal direction between the first direction and the second direction intersecting the first direction,
the plurality of openings is spaced apart from each other in a second diagonal direction intersecting the first diagonal direction, and
a length of each of the plurality of openings in the second diagonal direction is smaller than a diameter of the conductive particle.

11. The electronic device of claim 1, wherein the plurality of openings are arranged in a matrix shape defining a plurality of rows and a plurality of columns.

12. The electronic device of claim 1, wherein, in a plan view, the second pad extends in a first direction,
each of the plurality of openings has a circular shape, and
the plurality of openings are spaced apart from each other in the first direction and a second direction intersecting the first direction.

13. An electronic device, comprising:
a display panel including a first pad;
an electronic component electrically connected to the display panel; and
an adhesive layer bonding the display panel and the electronic component to each other,
wherein the electronic component comprises:
a second pad;
an insulating layer in which a plurality of openings exposing a portion of the second pad are defined; and
a contact electrode disposed on the insulating layer and connected to the second pad through the plurality of openings.

14. The electronic device of claim 13, wherein the first pad comprises:
a first conductive pattern;
a polymer pattern disposed on the first conductive pattern; and
a second conductive pattern disposed on the first conductive pattern and covering the polymer pattern.

15. The electronic device of claim 14, wherein, in a plan view, the second pad extends in a first direction,
each of the plurality of openings extends along the first direction,
the plurality of openings is spaced apart in a second direction intersecting the first direction, and
a length of each of the plurality of openings in the second direction is smaller than a length of the polymer pattern in the second direction.

16. The electronic device of claim 13, wherein the contact electrode comprises a first metal layer directly disposed on the second pad and a second metal layer disposed on the first metal layer,
wherein the first metal layer comprises titanium–tungsten (TiW) alloy, and the second metal layer comprises gold (Au).

17. The electronic device of claim 13, wherein the electronic component is a driving chip.

18. The electronic device of claim 13, wherein the electronic component does not include a bump protruding from the contact electrode.

19. An electronic component, comprising:
a driving integrated circuit;
a driving pad;
an insulating layer in which a plurality of openings exposing a portion of the driving pad are defined; and
a contact electrode disposed on the insulating layer and connected to the driving pad through the plurality of openings.

20. The electronic component of claim 19, wherein, in a plan view, the driving pad extends in a first direction,
each of the plurality of openings extends along the first direction, and
the plurality of openings is spaced apart in a second direction intersecting the first direction.
